(19) United States
(12) Patent Application Publication
(10) Pub. No.: US 2025/0372493 A1
(43) Pub. Date: Dec. 4, 2025

(54) ELECTRONIC DEVICE WITH INTERIOR AND PERIPHERAL LEADS

(71) Applicant: Texas Instruments Incorporated, Dallas, TX (US)

(72) Inventors: Francis De Vera, Baguio City (PH); Von Mark Mendoza, Baguio City (PH); Jesus Bautista, Jr., Baguio City (PH)

(21) Appl. No.: 18/679,724

(22) Filed: May 31, 2024

(51) Int. Cl. H01L 23/498; H01L 21/56; H01L 23/00; H01L 25/065

(52) U.S. Cl. CPC H01L 23/49838; H01L 21/56; H01L 24/16; H01L 24/48; H01L 24/49; H01L 24/73; H01L 24/81; H01L 25/0652; H01L 24/32; H01L 2224/16225; H01L 2224/32145; H01L 2224/48225; H01L 2224/49171; H01L 2224/73253; H01L 2224/73265; H01L 2224/81801; H01L 2924/1815

(57) ABSTRACT

An electronic device includes peripheral first leads, interior second leads, a first package structure extending on top sides of the peripheral first leads and interior second leads, and on upper first portions of lateral sides of the interior second leads, and a second package structure extending laterally around lower second portions of the lateral sides of the interior second leads, the second package structure exposing the bottom side of each of the peripheral first leads and exposing one lateral side of each of the peripheral first leads, the second package structure exposing the bottom side of each of the interior second leads.

### BACKGROUND

Electronic device packaging is a key part of continuing efforts to reduce system and device sizes while increasing power density and input/output (I/O) density. The flip-chip on lead (FCOL) small outline transistor (SOT) packages can provide good thermal performance, but these and other packaging solutions having functional leads on the edges of the package only do not allow increased I/O density without increasing the overall package dimensions or body size. Routable substrates and grid array packages (e.g., land grid array or LGA, ball grid array or BGA) packages can increase I/O density by increasing device height and require additional fabrication processing and increase the product cost.

### SUMMARY

In one aspect, an electronic device includes first leads individually having lateral sides, a top side, and a bottom side, as well a second leads individually having lateral sides, a top side, and a bottom side, and a first package structure on the semiconductor die, the top sides of the first leads, the top sides of the second leads, upper first portions of the lateral sides of the second leads, and the first package structure exposing one lateral side of each of the first leads. The electronic device also includes a second package structure extending laterally around lower second portions of the lateral sides of the second leads, the second package structure exposing the bottom side of each of the first leads, the second package structure exposing one lateral side of each of the first leads, the second package structure exposing the bottom side of each of the second leads.

In another aspect, a system includes a circuit board and an electronic device that has first leads having lateral sides, a top side, and a bottom side soldered to a respective conductive feature of the circuit board, and second leads having lateral sides, a top side, and a bottom side soldered to a respective conductive feature of the circuit board. The electronic device has first and second package structures, including a first package structure extending on the semiconductor die, the top sides of the first leads, the top sides of the second leads, upper first portions of the lateral sides of the second leads, and the first package structure exposing one lateral side of each of the first leads, and a second package structure extending laterally around lower second portions of the lateral sides of the second leads, the second package structure exposing the bottom side of each of the first leads, the second package structure exposing one lateral side of each of the first leads, the second package structure exposing the bottom side of each of the second leads.

In a further aspect, a method of fabricating an electronic device includes attaching a semiconductor die to a top side of a lead frame, the lead frame including a recess extending into the top side between a prospective first lead portion of the lead frame and a prospective second lead portion of the lead frame, electrically connecting the semiconductor die to one of the prospective first lead portion and the prospective second lead portion of the top side of the lead frame, performing a molding process that forms a package structure extending on the semiconductor die, on the top side of the lead frame, and into the recess, and separating the prospective second lead portion from the rest of the lead frame.

### BRIEF DESCRIPTION OF THE DRAWINGS

FIG. 1 is a sectional side elevation view of an example electronic device with peripheral and interior leads and upper and lower molded package structures taken along line 1-1 of FIG. 1A.

FIG. 1A is a bottom view of the electronic device of FIG. 1 showing peripheral and interior leads in an array configuration.

FIG. 1B is a sectional side elevation view the electronic device taken along line 1B-1B of FIG. 1A.

FIG. 1C is a partial sectional top plan view of the electronic device taken along line 1C-1C of FIGS. 1 and 1B.

FIG. 1D is a partial sectional side elevation view showing further details of example peripheral and interior leads in the electronic device of FIGS. 1-1C.

FIG. 1E is a sectional side elevation view of another electronic device example with peripheral stub leads and interior leads and upper and lower molded package structures taken along line 1E-1E of FIG. 1F.

FIG. 1F is a bottom view of the electronic device of FIG. 1E with peripheral stub leads on four lateral sides.

FIG. 1G is a top view of the electronic device of FIGS. 1E and 1F with peripheral stub leads on four lateral sides.

FIG. 1H is a top view of another example implementation of the electronic device example of FIG. 1E with peripheral stub leads on two opposite lateral sides.

FIG. 1I is a sectional side elevation view of another example electronic device with peripheral and interior leads with a bottom side die attach pad heat spreader and upper and lower molded package structures taken along line 1I-1I of FIGS. 1J and 1K.

FIG. 1J is a bottom view of the electronic device of FIG. 1I with the bottom side die attach pad heat spreader and peripheral and interior leads.

FIG. 1K is a partial sectional top plan view of the electronic device taken along line 1K-1K of FIG. 1I.

FIG. 2 is a flow diagram of a method of fabricating an electronic device.

FIGS. 3-12 are partial sectional side elevation and top views of the electronic device of FIGS. 1-1D undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

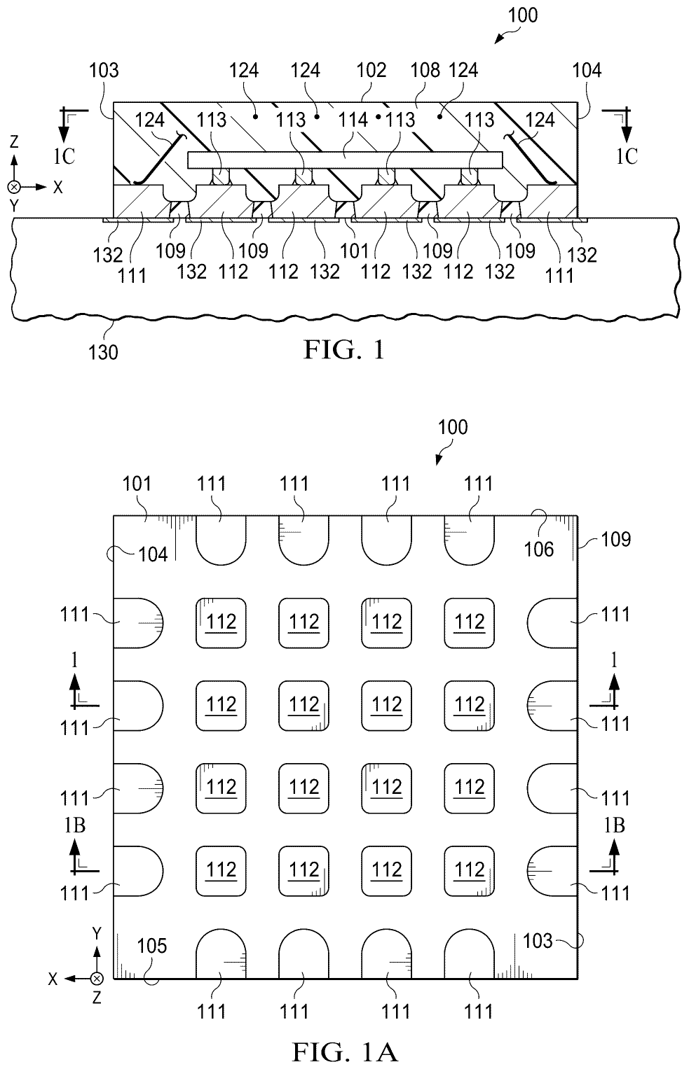

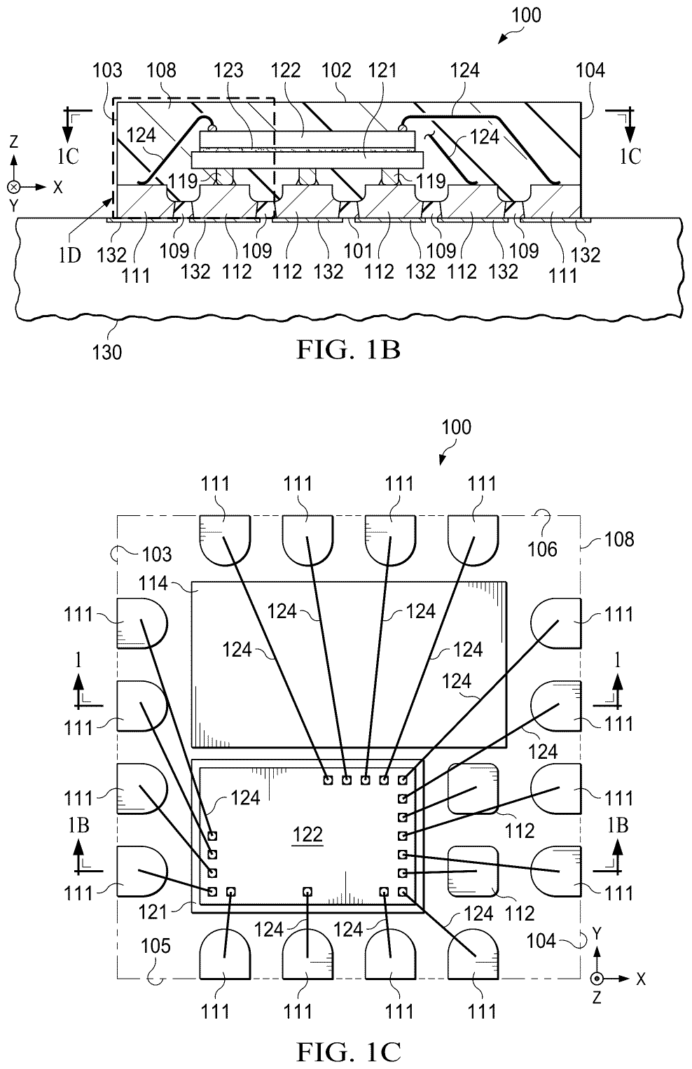

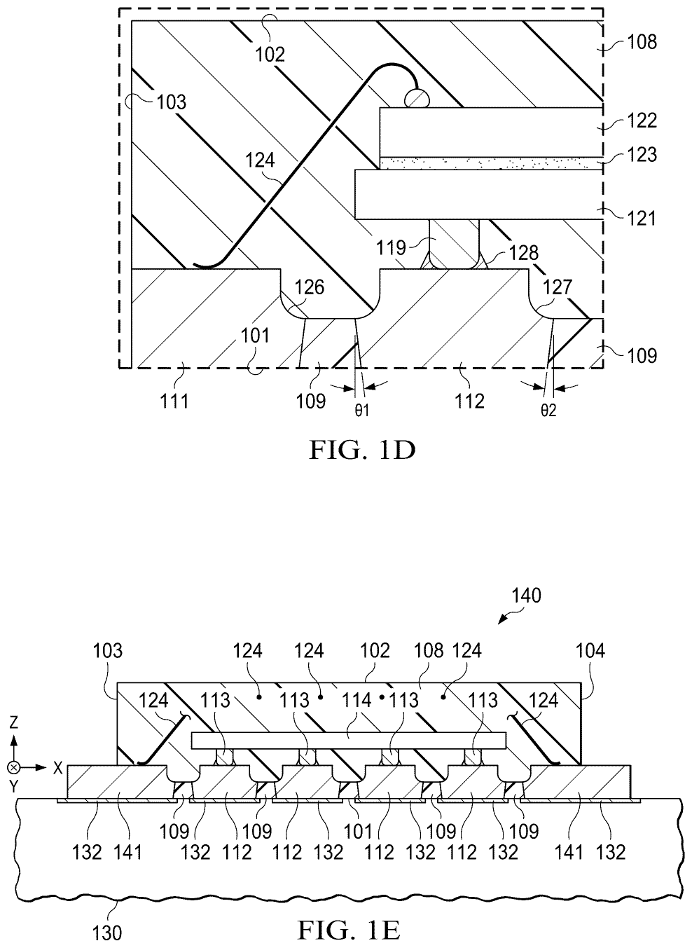

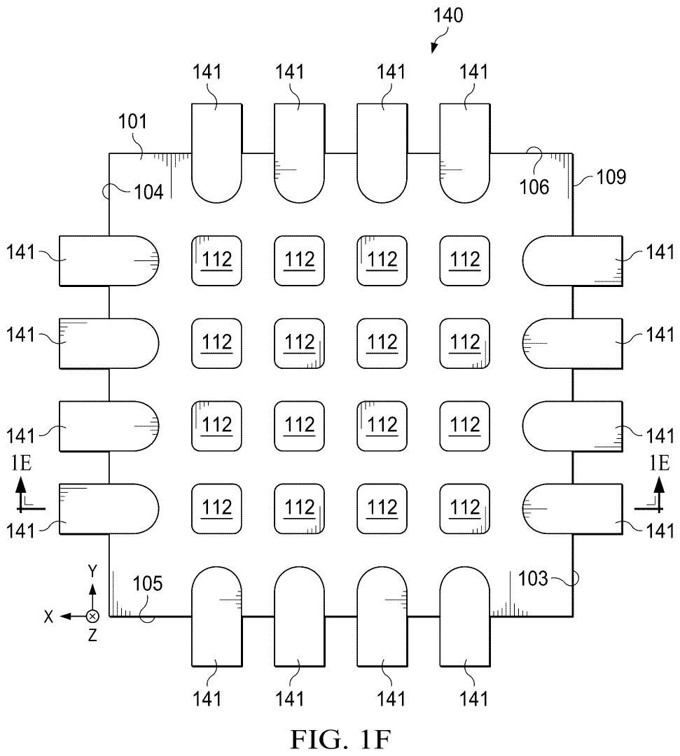

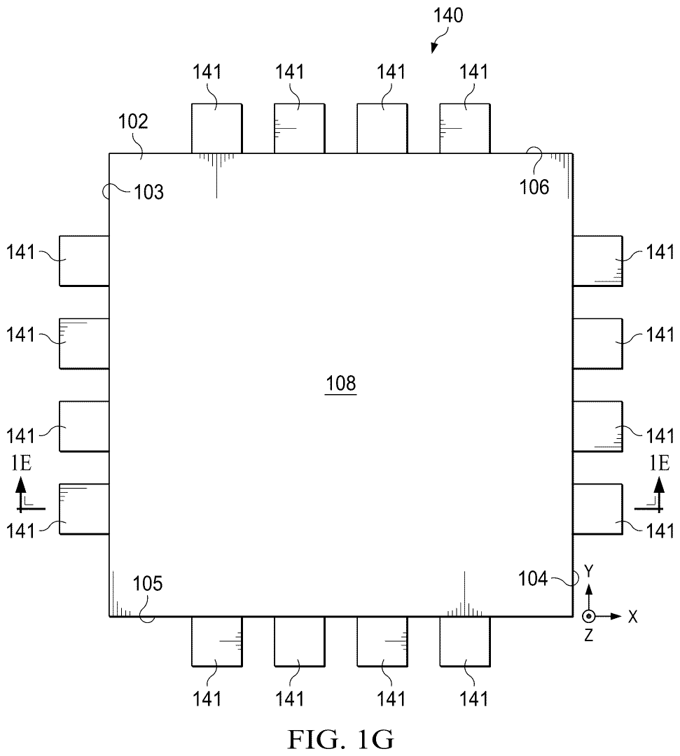

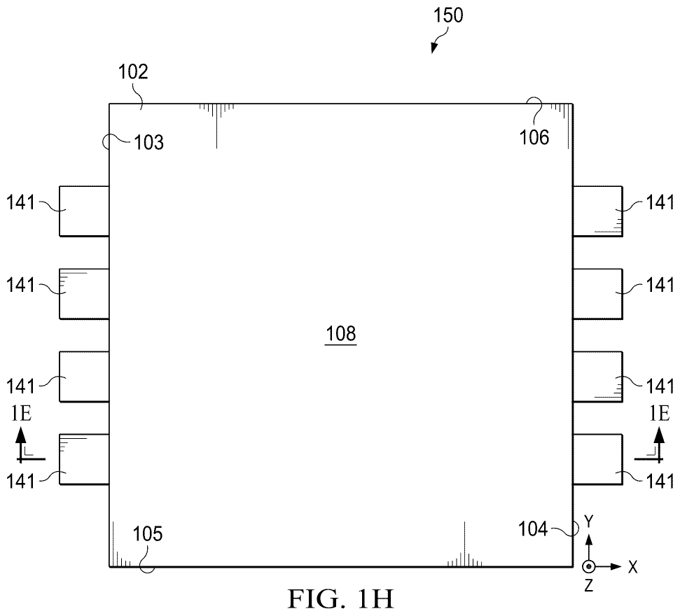

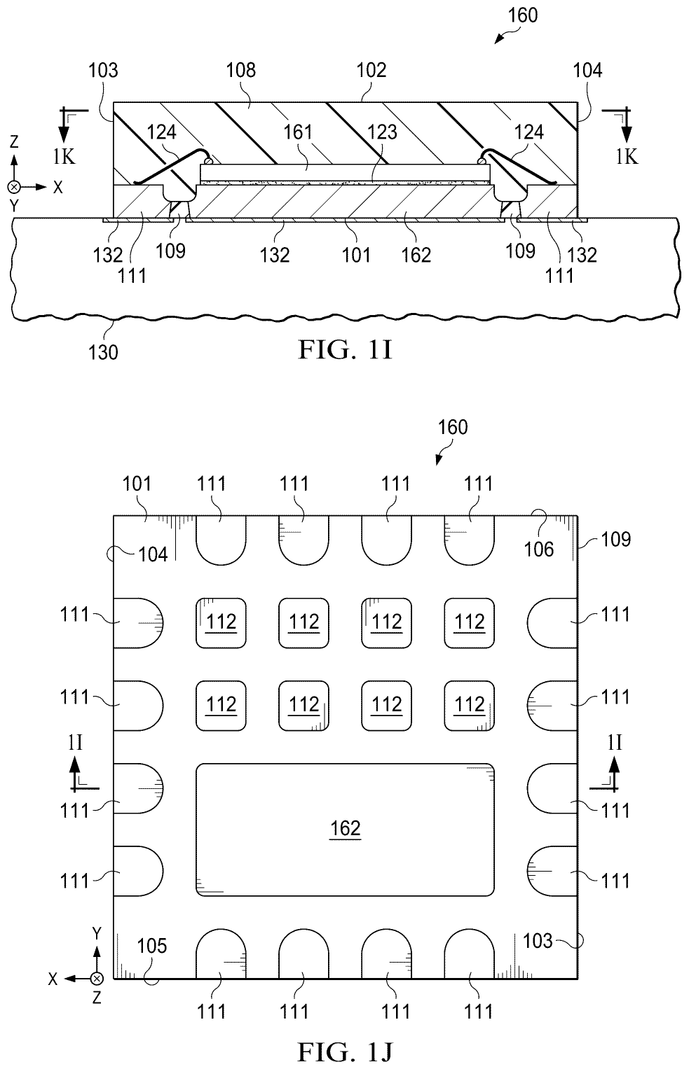

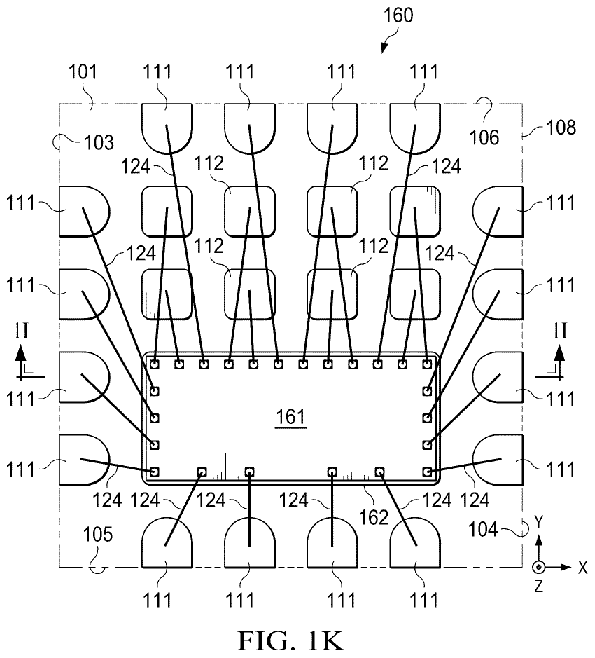

Referring initially to FIGS. 1-1D, FIG. 1 shows a side section view of an example electronic device 100 taken along line 1-1 of FIG. 1A. FIG. 1A shows a bottom view of the electronic device 100, FIG. 1B shows a sectional side view taken along line 1B-1B of FIG. 1A, FIG. 1C shows a top section view of the electronic device 100 taken along line 1C-1C of FIGS. 1 and 1B, and FIG. 1D shows a side section view to illustrate further details of example peripheral first leads 111 and interior second leads 112 in the electronic device 100. The electronic device 100 is illustrated in FIGS. 1-1D in an example position in a three-dimensional space with respective first, second, and third mutually orthogonal directions X, Y (FIGS. 1A and 1C), and Z (FIGS. 1, 1B, and 1D). As best shown in FIGS. 1, 1B and 1D, the electronic device 100 includes opposite first and second (e.g., bottom and top) sides 101 and 102 that are spaced apart from one another along the third direction Z. The electronic device 100 also includes third and fourth sides 103 and 104 that are spaced apart from one another along the first direction Y, and fifth and sixth sides 105 and 106 (FIGS. 1A and 1C) that are spaced apart from one another along the second direction Y.

The example electronic device 100 has respective first and second (e.g., upper and lower) package structures 108 (FIGS. 1 and 1B-1D) and 109 (FIGS. 1-1B and 1D) that include or define the lateral sides 103-106. In one example, the first and second package structures 108 and 109 are made of the same material, such as epoxy molding compound (EMC). Different materials can be used for one or both of the first and second package structures 108 and 109 in other implementations. In the illustrated example, the first and second (e.g., bottom and top) sides 101 and 102 are approximately planar and extend in respective X-Y planes of the first and second directions X and Y, although strict planarity is not a requirement of all possible implementations. The first package structure 108 defines the second side 102. In the illustrated example, the lower second package structure 109 extends to the first side 101. The laterally opposite third and fourth sides 103 and 104 are approximately planar and extend in respective Y-Z planes of the second and third directions. The laterally opposite fifth and sixth sides 105 and 106 are approximately planar and extend in respective X-Z planes of the first and sixth sides 101 and 106. The lateral sides 103-106 may be slightly angled with respect to the above-mentioned planes, for example, as a result of molding operations using mold cavities having slight angles to facilitate disengagement of the molds one forming the respective first and second package structures 108 and 109.

The electronic device 100 includes conductive peripheral first leads 111 along the lateral sides 103-106 to form a quad flat no-lead (QFN) style package structure. In another implementation the device has conductive leads on two opposite sides to provide a dual flat no-lead (DFN) package structure (not shown). In further examples, some or all of the peripheral first leads 111 can be stub leads that extend outward from the respective lateral side 103-106 (e.g., FIGS. 1E-1H below). The peripheral first leads 111 are partially enclosed by the package structure 108 and the peripheral first leads 111 in one example are or include copper (Cu). As best shown in FIG. 1B, the individual peripheral first leads 111 have a first (e.g., bottom) surface and a lateral side (e.g., sidewall) with a surface exposed outside the package structures 108 and 109. The first leads 111 are referred to herein as peripheral first leads with respective outer lateral sides exposed outside an associated one of the lateral device sides 103-106, as best shown in FIG. 1A. In one example, the peripheral first leads 111 are or include copper and the bottom and exposed lateral sides of the peripheral first leads 111 can be plated or unplated.

The electronic device 100 includes conductive metal interior leads 112 with bottom sides exposed along the first side 101 of the electronic device 100 but are not positioned along any of the lateral sides 103-106 of the electronic device 100. In one example, the interior second leads 112 are or include copper and the bottom sides of the interior second leads 112 can be plated or unplated. In one example, the peripheral first leads 111 and the interior second leads 112 are of the same material, for example, copper material from a common starting lead frame.

As best shown in the bottom view of FIG. 1A, the peripheral first leads 111 and the interior second leads 112 can be positioned in an array of rows and columns, for example, in a standard configuration of a BGA or LGA device to allow installation in a host circuit board with patterned conductive features arranged in a standard configuration. In other examples, different configurations of the peripheral first leads 111 and/or the interior second leads 112. As further shown in FIG. 1A, the provision of the interior second leads 112 advantageously doubles the number of external connections (e.g., doubles the I/O density) of the electronic device 100 compared with a corresponding QFN package having only peripheral leads. For example, the illustrated electronic device 100 includes 32 leads 111 and 112, whereas a corresponding QFN device of the same package size would have only 16 leads. In other implementations, different numbers of leads can be used, including any combination of peripheral first leads 111 with respective lateral sides exposed on one or more lateral sides 103-106 of the electronic device 100, and interior second leads 112 that have no lateral sides exposed outside the package structure 108, 109. In further implementations (e.g., FIGS. 1I-1K below) one or more of the interior second leads can be configured to extract heat from an attached semiconductor die, for example, and can operate as a conductive lead connected to an electrical terminal of such a semiconductor die and/or one or more of the interior second leads can operate as a die attach pad for mounting an attachment of an associated semiconductor die, or a portion thereof, without being electrically connected to any terminal of the attached semiconductor die, and may operate as a thermal heat extraction structure (e.g., heatsink) to remove heat from the attached semiconductor die.

The peripheral first leads 111 in the illustrated example each have four lateral sides, a top side, and a bottom side. In the illustrated example, each of the interior second leads 112 has four lateral sides, a top side, and a bottom side. One or more of the peripheral first leads 111 and one or more of the interior second leads 112 operate as electrical connections between circuitry of the electronic device 100 and a system circuit board (e.g., PCB 130 in FIG. 1) in which the electronic device 100 is installed, either by direct soldering as shown in FIG. 1 or by installation into a socket (not shown) of a host system or circuit board. In various implementations, the top sides of some or all of the peripheral first leads 111 and a some or all of the interior second leads 112 are electrically connected by flip-chip soldering and/or by bond wire electrical connection to circuitry of the electronic device 100. In various examples, the electronic device 100 can include one or more semiconductor dies and/or other electronic components, such as passive surface mount components (e.g., resistors, capacitors, inductors, diodes, etc.) and/or active components, such as transistors, etc. The illustrated example electronic device 100 includes a first semiconductor die 114 with conductive metal features or terminals 113 (e.g., copper pillars or posts) soldered to the top sides of corresponding ones of the interior second leads 112 as shown in FIG. 1, in an attachment referred to herein as flip-chip soldering or flip-chip attachment.

As shown in FIGS. 1B-1D, the illustrated electronic device 100 also includes a second semiconductor die 121 with conductive metal features or terminals 119 (e.g., copper pillars or posts) soldered to the top sides of corresponding ones of the interior second leads 112 by solder 128 (FIG. 1D) by flip-chip soldering techniques. In addition, the electronic device 100 includes a third semiconductor die 122 with a bottom side attached to a top side of the second semiconductor die 121 by a die attach adhesive 123 (FIGS. 1B and 1D). The third semiconductor die 122 includes conductive features (e.g., bond pads) that are electrically connected to corresponding ones of the peripheral first leads 111 and interior second leads 112 by corresponding bond wires 124, as best shown in FIGS. 1B-1D. In other implementations, any suitable combination of one or more semiconductor dies can be interconnected with one another and/or with one or more of the peripheral first leads 111 and the interior second leads 112 by flip chip solder attachment and/or by bond wire connection, alone or in combination with further passive or active electronic components (not shown, e.g., surface mount components with solder connections to respective ones of the leads 111 and/or 112).

As best shown in FIGS. 1, 1B, and 1D, the first package structure 108 extends on the semiconductor dies 114, 121 and 122. The first package structure 108 also extends on the top sides of the peripheral first leads 111 and the top sides of the interior second leads 112, and the first package structure 108 encloses the bond wires 124. In addition, the first package structure 108 extends on upper first portions of three lateral sides of the peripheral first leads 111, and the first package structure 108 exposes one lateral side of each of the peripheral first leads 111 along a respective one of the lateral device sides 103-106. The first package structure 108 also extends on upper first portions of all four lateral sides of the interior second leads 112.

The second package structure 109 extends laterally around lower second portions of three the lateral sides each of the peripheral first leads 111. The second package structure 109 also extends laterally around lower second portions of the lateral sides of the interior second leads 112. In addition, the second package structure 109 exposes the bottom side of each of the peripheral first leads 111. The second package structure 109 exposes a lower portion of one lateral side of each of the peripheral first leads 111, and the second package structure 109 exposes the bottom side of each of the peripheral first leads 111 and interior second leads 112. In the illustrated example, the second package structure 109 extends to the first side 101 (e.g., the bottom side) of electronic device 100 and the bottom sides of the first and second leads 111 and 112 are substantially coplanar with the bottom side of the second package structure 109, although not a requirement of all possible implementations. For example, the bottom sides of the leads 111 and/or 112 may extend slightly downward beyond the bottom side of the second package structure 109 in other implementations.

The electronic device 100 is installed in FIG. 1 in an electrical system with at least some of the peripheral first leads 111 and at least some of the interior second leads 112 soldered to conductive features 132 of a system printed circuit board (PCB) 130. The first and second semiconductor dies 114 and 121 are electrically connected by direct flip-chip soldering to corresponding ones of the interion second leads 112. As further shown in FIG. 1C, the third semiconductor die 122 is electrically connected by bond wires 124 to corresponding ones of the peripheral first leads 111 and to corresponding one of the interior second leads 112. The leads 111 and 112 provide high I/O count for electrical connection to the circuitry of the semiconductor dies 114, 121 and 122 to the circuit board 130.

As further shown in FIG. 1D, the leads 111 and 112 provide features that facilitate mold locking and mitigate delamination or separation of the mold material 108, 109 from the leads 111 and 112. The upper first portions of the lateral sides of the peripheral first leads 111 have an outward taper in a direction toward a bottom side 101 of the electronic device 100. In the illustrated example, the upper first portions of the lateral sides of the peripheral first leads 111 have a curved surface 126 with an outward taper. The lower second portions of the lateral sides of the peripheral first leads 111 have an inward taper in the direction toward the bottom side 101 of the electronic device 100. In the example of FIG. 1D, the lower second portions of the lateral sides of the peripheral first leads 111 have an inwardly tapered profile that extends at an angle θ1 to the third direction Z. Also, the upper first portions of the lateral sides of the interior second leads 112 have an outward taper in the direction toward the bottom or first side 101 of the electronic device 100, and the lower second portions of the lateral sides of the interior second leads 112 have an inward taper in the direction toward the bottom side 101 of the electronic device 100. The upper first portions of the lateral sides of the interior second leads 112 have a curved surface 127 with an outward taper, and the lower second portions of the lateral sides of the interior second leads 112 have an inwardly tapered profile that extends at an angle θ2 to the third direction Z. The outwardly tapered upper portions and inwardly tapered lower portions of the lateral sides of the leads 111 and 112 helps adhere the molding compound of the package structures 108 and 109 to the peripheral first leads 111 and the interior second leads 112 to prevent or mitigate delamination during production and operation of the electronic device 100.

FIGS. 1E-1K show further examples, including an electronic device 140 in FIGS. 1E-1G with similarly numbered structures and features as described above in connection with the device 100 of FIGS. 1-1D. The electronic device 140 has peripheral first stub leads 141 that extend outward from the respective lateral side 103-106 and include flat bottom sides that can be soldered to a circuit board or installed into a device socket (not shown). As shown in the respective bottom and top views of FIGS. 1F and 1G, the electronic device 140 has peripheral first stub leads 141 that extend outward from all four lateral sides 103-106, along with internal second leads 112 and first and second package structures 108 and 109 as previously described.

FIG. 1H shows another example electronic device 150 with similarly numbered structures and features as described above in connection with the device 100 of FIGS. 1-1D, as well as peripheral stub leads 141 on two opposite lateral sides 103 and 104 and interior second leads 112, with first and second package structures 108 and 109 as described above. In one implementation, the electronic device 150 has flush (e.g., no-lead) peripheral first leads (not shown) on the other lateral sides 105 and 106. In a further example, the electronic device 150 can have no peripheral first leads along the sides 105 and 106.

FIGS. 1I-1K show another example electronic device 160 having similarly numbered structures and features as described above in connection with the device 100 of FIGS. 1-1D, including flush peripheral first leads 111 along four lateral sides 103-106 and interior leads 112 (FIGS. 1J and 1K). In addition, the electronic device 160 of FIGS. 1I-1K has first and second package structures 108 and 109 as described above. The electronic device 160 has a further interior second lead 162 that is or includes conductive metal or other thermal conductor (e.g., copper) with an exposed bottom side that can be plated or unplated. The bottom side of the further interior second lead 162 in the illustrated example operates as a die attach pad to support a semiconductor die 161 attached to a top side thereof by a die attach adhesive 123. The further interior second lead 162 has a bottom side or surface that is exposed along the bottom or first side 101 and is configured to extract heat from the semiconductor die 161 attached to the top side thereof. The bottom side of the interior second lead 162 in one example is approximately coplanar with the first side 101 of the device 160 and can be soldered to a conductive pad 132 of a host circuit board 130 as shown in FIG. 1I or installed into a socket (not shown). When installed, the interior second lead 162 can draw heat downward out of the semiconductor die 161 and into the conductive feature 132 of the circuit board 130 as shown in FIG. 1I. As further shown in FIGS. 1J and 1K, the example electronic device 160 has other interior second leads 112 that provide additional electrical connections beyond the I/O count of the peripheral first leads 111. The circuitry of the semiconductor die 161 is connected by bond wires 124 to certain of the peripheral first leads 111 and the interior second leads 112. This and other examples help increase I/O density without increasing device size and can benefit thermal performance with mold locking capabilities to enhance structural reliability.

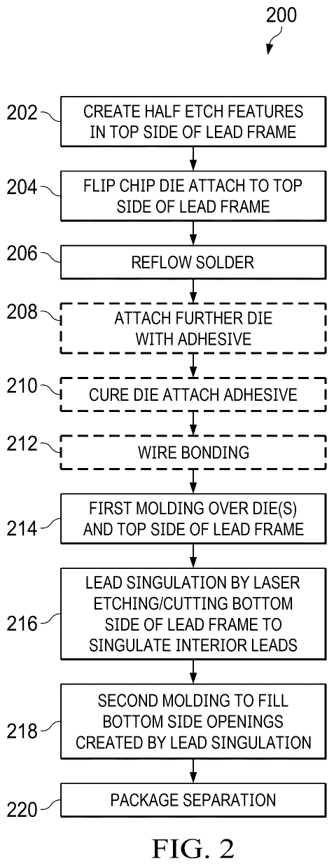

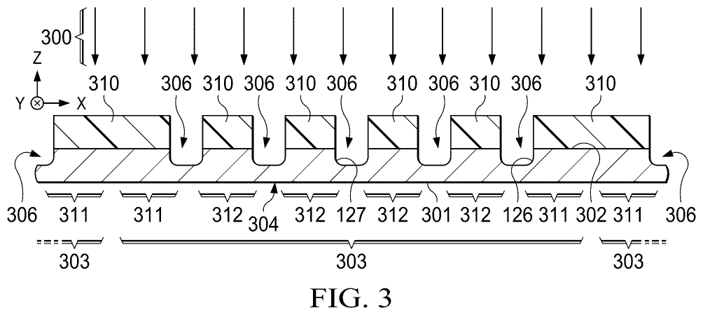

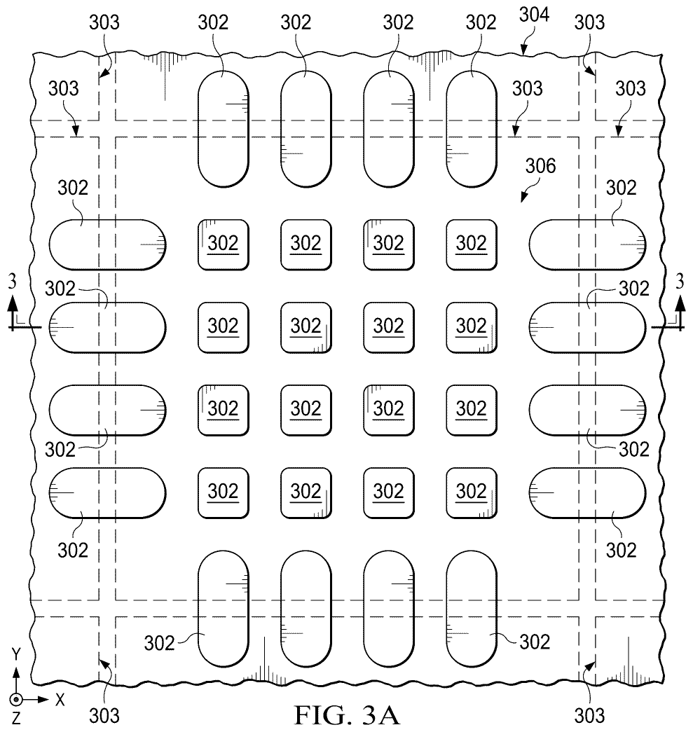

Referring also to FIGS. 2-12, FIG. 2 shows a method 200 of fabricating an electronic device and FIGS. 3-12 show the electronic device 100 of FIGS. 1-1D undergoing fabrication processing according to an implementation of the method 200. The method 200 in one example uses a lead frame in the form of a panel array structure with rows and columns of unit areas that individually correspond to a prospective finished instance of the electronic device 100. In one example, the lead frame has recessed areas that can be formed or otherwise created at 202 in FIG. 2 by machining, stamping, etching, and/or other suitable manufacturing techniques. FIGS. 3 and 3A show one example, in which a chemical etch process 300 is performed on a lead frame 304 having opposite first and second (e.g., bottom and top) sides 301 and 302. The etch process 300 forms a recess 306 that extends into the top side 302 between a prospective peripheral first lead portion 311 of the lead frame 304 and a prospective interior second lead portion 312 of the lead frame 304 as best shown in FIG. 3. The etch process 300 is performed (e.g., FIG. 3) using an etch mask 310 that covers the prospective peripheral first lead portions 311 of the lead frame 304 and the prospective interior second lead portions 312 in each unit area 303 of the lead frame 304 panel array structure, a portion of which is shown in the top view of FIG. 3A, with the prospective peripheral first lead portions 311 extending across scribe street regions between adjacent unit areas 303 of the lead frame 304.

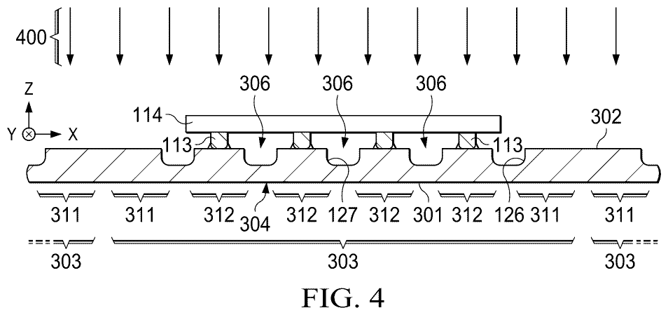

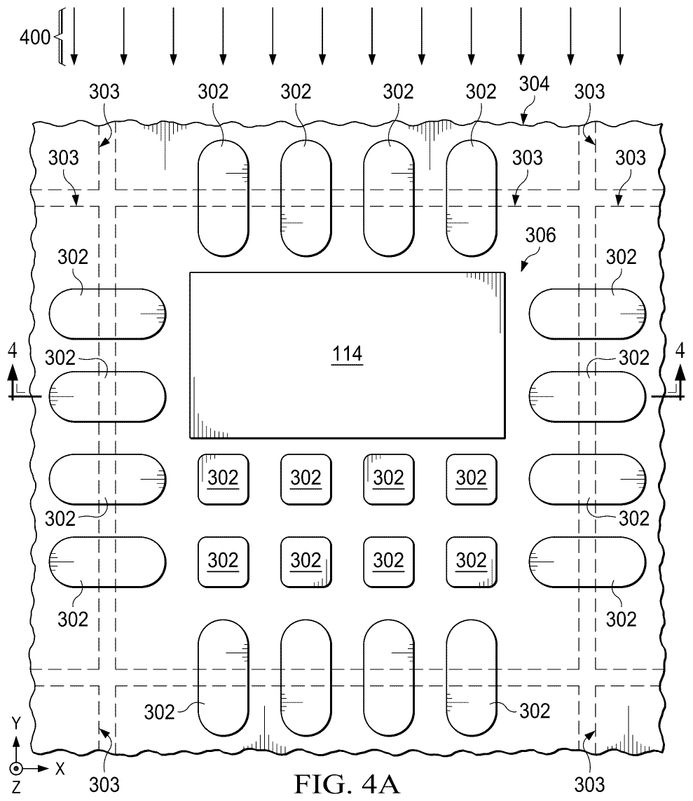

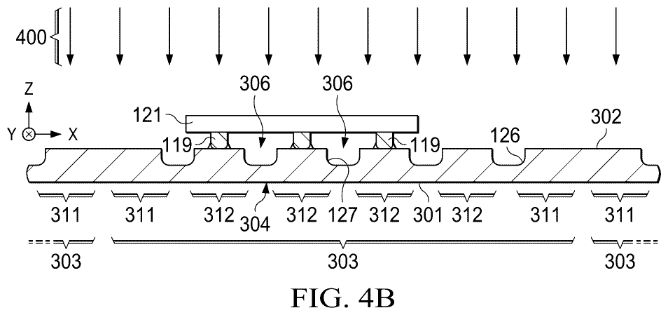

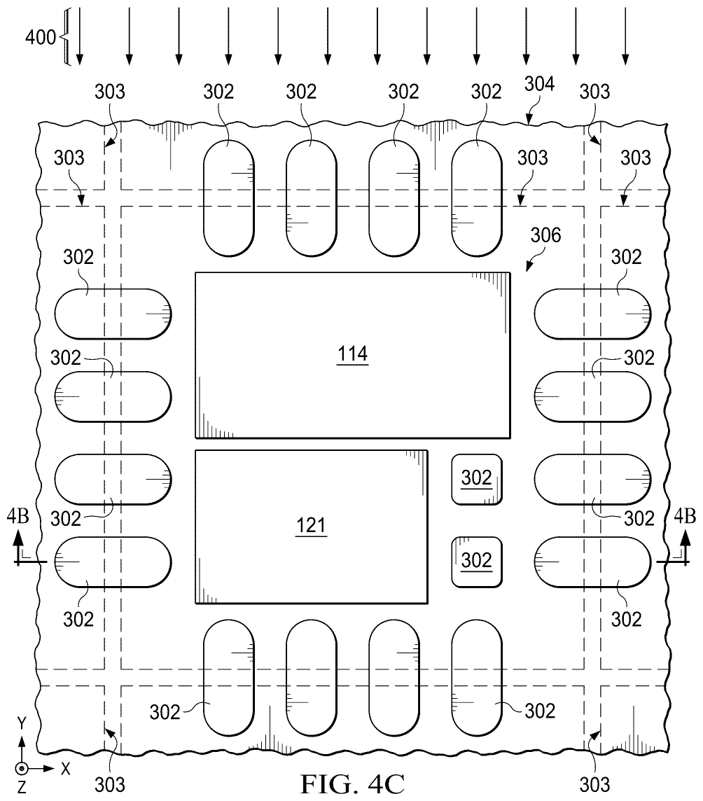

The method 200 includes die attach processing at 204 in FIG. 2. FIGS. 4-4C show one example, in which a flip-chip die attach process 400 is performed that attaches the terminals 113 of the first semiconductor die 114 to the top sides of corresponding ones of the prospective interior second leads 312 as shown in FIGS. 4 and 4A. In one example, the die attach process 400 includes concurrent or sequential placement of multiple dies to respective unit areas 303 of the lead frame panel array 301. In one example, the die attach process 400 uses automated pick and place equipment (not shown) to attach an instance of the first semiconductor die 114 in each unit area 303 of the panel array structure.

The die attachment process 400 in one example can include dispensing, printing, silk screening, or other form of providing die attach adhesive (not shown) in each unit area of the panel array structure, followed by pick and place attachment of individual semiconductor dies 120 in each unit area. In another example, flip chip die attachment processing is performed, including silk screening or otherwise providing solder paste along selected portions of the starting lead frame 301 and placement of individual instances of the first semiconductor die 114 with conductive bond pads 113 thereof engaging the solder paste for subsequent solder reflow processing.

In the illustrated example, the die attach process 400 continues in FIGS. 4B and 4C with flip-chip attachment of the second semiconductor die 121 in each unit area 303 of the lead frame panel array 304 with corresponding terminals 119 attached (e.g., by solder paste) to the top sides of corresponding ones of the prospective interior second leads 312 as shown in FIGS. 4B and 4C. The die attach processing 400 attaches the semiconductor dies 114 and 121 to the top side 302 of the lead frame 304 having the recess 306 extending into the top side 302 between prospective peripheral first lead portions 311 and the prospective interior second lead portions 312.

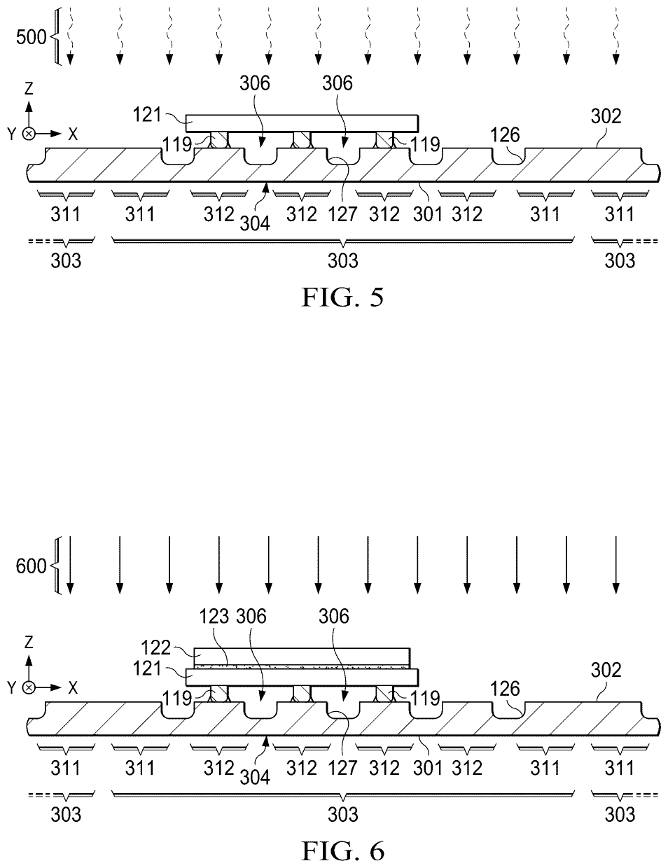

The method 200 continues at 206 in FIG. 2 with thermal processing to reflow the solder paste and complete the flip-chip soldering of the terminals 113 and 119 of the first and second semiconductor dies 114 and 121 to the respective prospective interior second leads 312. FIG. 5 shows one example, in which a thermal process 500 is performed that reflows the solder paste to solder the terminals 119 of the second semiconductor die 121 to the respective prospective interior second leads 312 as shown and to concurrently solder the terminals 113 of the first semiconductor die 121 to the corresponding prospective interior second leads (not shown in the section view of FIG. 5).

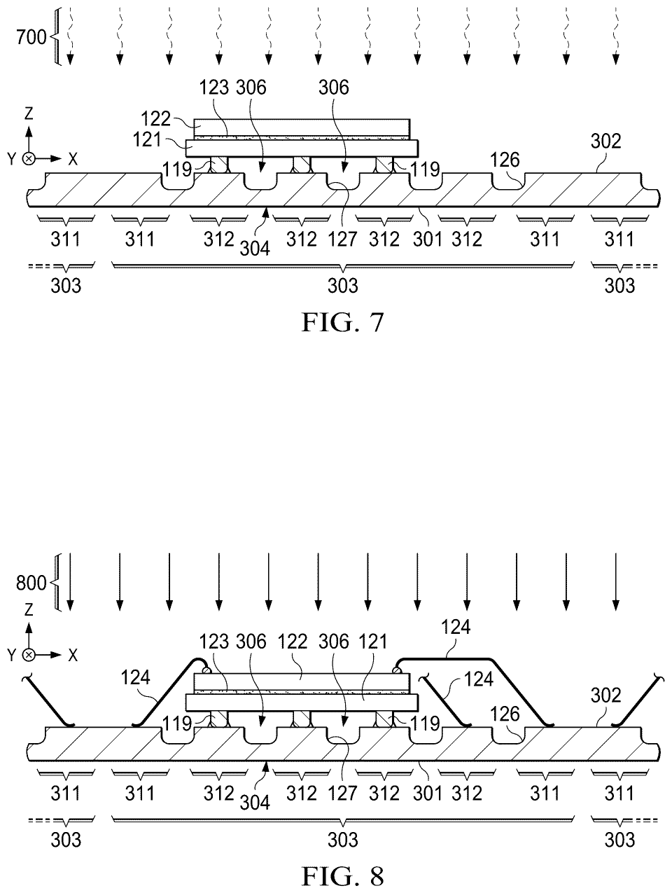

The method 200 in one example continues with further die attachment at 208 in FIG. 2. FIG. 6 shows one example, in which a die attach process 600 is performed that attaches the third semiconductor die 122 in each unit area 303 with a bottom side attached to a top side of the second semiconductor die 121 via die attach adhesive 123. The die attach process 600 in one example can include optional adhesive curing at 210 in FIG. 2. FIG. 7 shows one example, in which a thermal curing process 700 is performed that cures the die attach adhesive 123. Different curing processes can be used in other examines, such as UV, ultrasonic, etc.

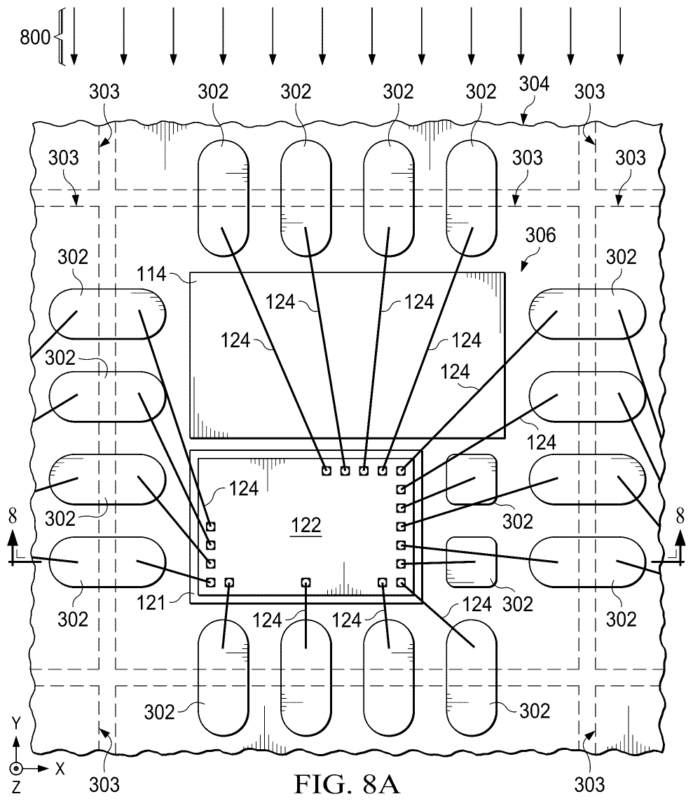

At 212 in FIG. 2, the method 200 continues with electrical coupling including coupling one or more conductive terminals (e.g., bond pads) of the third 122 to respective prospective peripheral first leads 311 and prospective interior second leads 312, as well as any die-to-die connections and/or connections to passive components (not shown) required for a given electronic device design. FIG. 8 shows one example, in which a wire bonding process 800 is performed that forms bond wires 124 between respective conductive bond pads of the third semiconductor die 122 and associated ones of the prospective peripheral first leads 311 and prospective interior second leads 312.

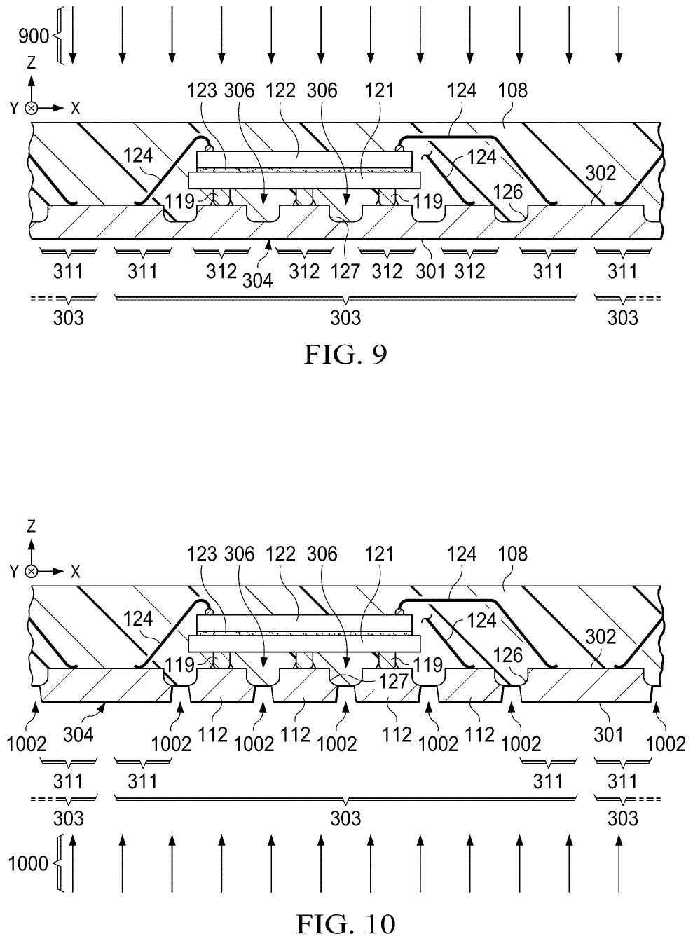

The method 200 continues at 214 in FIG. 2 with first molding processing to cover the dies 114 and the top side 302 of the lead frame 304. FIG. 9 shows one example, in which a first molding process 900 is performed that forms the first package structure 108 extending on the semiconductor dies 114, 121 and 122, on the top side 302, and extending into the recess 306 of the lead frame 304. The first molding process 900 in one example fills the recess 306 in each unit area 303 as shown in FIG. 9. In one example, the first molding process 900 is performed using a first mold (not shown) with a single cavity that includes all the unit areas 303 of the lead frame panel array structure 304. In other examples, a first mold can be used that includes multiple mold cavities (not shown), for example, for individual unit areas 304 or groups thereof (e.g., rows and/or columns, etc.).

The method continues at 216 in FIG. 2 with lead singulation to separate the prospective interior second lead portion 312 from the rest of the lead frame 304. FIG. 10 shows one example, in which a separation process 1000 is performed that singulates the interior second leads 112 from the rest of the lead frame 304, including separating the interior second leads 112 from one another and from each of their respective nearest neighboring structures of the starting lead frame 304, including separating some of the interior starting leads 112 from a neighboring prospective peripheral first lead 311 of the lead frame 304. In one example, the separation or lead singulation process 1000 is a laser process, such as a laser etching, laser cutting, or laser ablation process using a laser (not shown), for example, translated along the first and second directions X and Y along the bottom side of the lead frame panel array structure 304 by automated robotic equipment (not shown). In other implementations, a different type or form of separation process and equipment can be used, such as saw cutting, chemical etching, etc. The separation process 1000 forms the interior second leads 112 that are individually spaced apart from the rest of the lead frame 304 and having lateral sides, a top side, and a bottom side. In certain implementations (e.g., FIGS. 1I-1J above), the separation process 1000 can separate different shapes of interior second leads that can operate as interior die attach pads and/or interior heat sink structures from the rest of the starting lead frame 304 in one or more of the unit areas 303. In one example, the separation process 1000 removes material from the bottom side 301 of the lead frame 304 to create openings 1002 that expose a portion of the package structure 108 in the recess 306 as shown in FIG. 10.

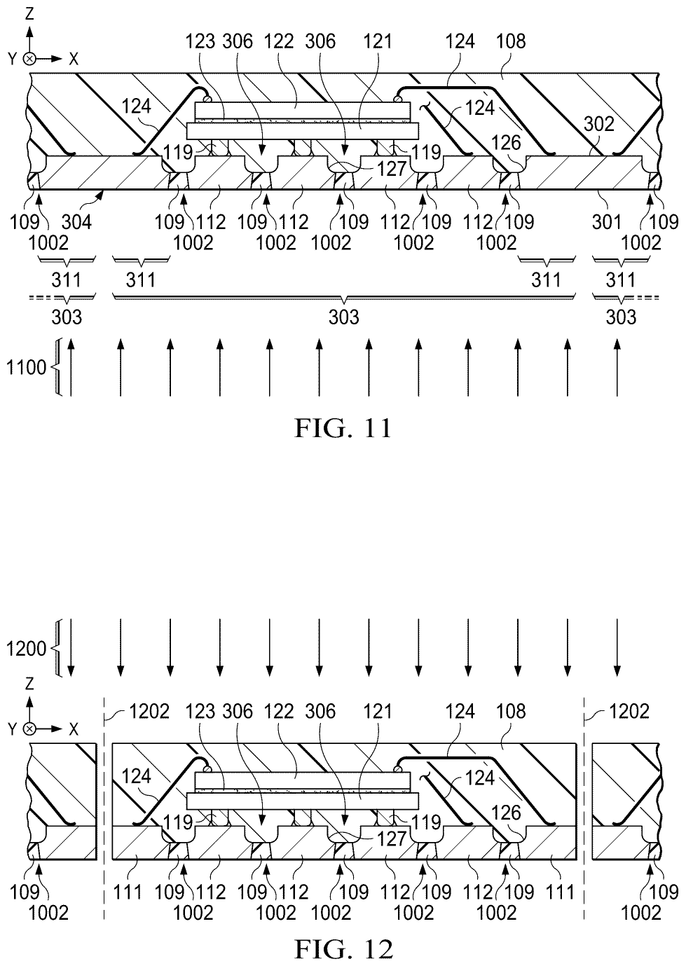

The method 200 in FIG. 2 in one example further includes a second molding process at 218. FIG. 11 shows one example, in which a second molding process 1100 is performed that forms the second package structure 109 that extends laterally around lower second portions of the lateral sides of the interior second leads 112, and the second package structure 109 exposes the bottom side of the interior second leads 112. In addition, the second package structure 109 formed by the process 1100 extends laterally around the prospective peripheral first leads 311 and exposes the bottom sides thereof prior to device singulation.

The method 200 in one example further includes package separation at 220 in FIG. 2. FIG. 12 shows one example, in which a package separation process 1200 is performed that separates individual packaged electronic devices 100 from the panel array structure along lines 1202 (e.g., along scribe streets between adjacent unit areas 303). Any suitable separation process 1200 can be used, such as saw cutting, laser cutting, chemical etching, etc. The package separation process 1200 in the illustrated example cuts through the prospective peripheral first leads 311 (e.g., FIG. 11) to define the exposed lateral sides of the separated peripheral first leads 111 (e.g., FIG. 12) that are exposed outside the package structures 108 and 109 along the respective lateral side 103-106 of the finished package structure (e.g., FIGS. 1-1D above).

Described examples advantageously increase the lead count and I/O density for a given packaged electronic device body size without requiring extra processing associated with land grid array or ball grid array structures that use routable package substrates. Certain disclosed examples increase I/O density by adding functional interior leads under the package from material of a single starting lead frame, where the peripheral first leads 111 and the interior second leads 112 include the same material. In certain examples, the first and second molded package structures 108 and 109 are formed of the same molding material, such as epoxy molding compound (EMC). Various implementations can use the created interior second leads 112, 162 for electrical connections (e.g., to increase I/O density) and/or for supporting semiconductor dies (e.g., lead 162 in FIGS. 1I-1K above), and electrical interconnections can be formed by any suitable techniques and processing equipment (e.g., flip-chip die attachment and soldering, wire bonding, etc.), and the described examples can include multichip module type devices with or without additional integrated passive or active circuit components such as surface mount capacitors, resistors, transistors, etc., and the interior features created by the disclosed techniques can be used to help thermal dissipation from the package body in certain implementations.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
peripheral first leads, each peripheral first lead having lateral sides, a top side, and a bottom side;
interior second leads, each interior second lead having lateral sides, a top side, and a bottom side;
a first package structure extending on the top sides of the peripheral first leads, the top sides of the interior second leads, upper first portions of the lateral sides of the interior second leads, and the first package structure exposing one lateral side of each of the peripheral first leads; and
a second package structure extending laterally around lower second portions of the lateral sides of the interior second leads, the second package structure exposing the bottom side of each of the peripheral first leads, the second package structure exposing one lateral side of each of the peripheral first leads, the second package structure exposing the bottom side of each of the interior second leads.

2. The electronic device of claim 1, further comprising a semiconductor die electrically connected to one of the peripheral first leads and to one of the interior second leads.

3. The electronic device of claim 1, wherein the peripheral first leads and the interior second leads are of the same material.

4. The electronic device of claim 1, wherein the second package structure extends to a bottom side of electronic device.

5. The electronic device of claim 1, wherein the first and second package structures include epoxy molding compound.

6. The electronic device of claim 1, further comprising a semiconductor die flip-chip attached to electrically connected to one of the interior second leads.

7. The electronic device of claim 1, further comprising a wire bond connected between a semiconductor die and one of the interior second leads.

8. The electronic device of claim 1, wherein a semiconductor die is attached to one of the interior second leads and the one of the interior second leads is configured to extract heat from the semiconductor die.

9. The electronic device of claim 1, wherein:
the upper first portions of the lateral sides of the interior second leads have an outward taper in a direction toward a bottom side of the electronic device; and
the lower second portions of the lateral sides of the interior second leads have an inward taper in the direction toward the bottom side of the electronic device.

10. A system, comprising:
a circuit board having a conductive feature; and
an electronic device, including:
peripheral first leads, each peripheral first lead having lateral sides, a top side, and a bottom side soldered to a respective conductive feature of the circuit board;
interior second leads, each interior second lead having lateral sides, a top side, and a bottom side soldered to a respective conductive feature of the circuit board;
a first package structure extending on the top sides of the peripheral first leads, the top sides of the interior second leads, upper first portions of the lateral sides of the interior second leads, and the first package structure exposing one lateral side of each of the peripheral first leads; and
a second package structure extending laterally around lower second portions of the lateral sides of the interior second leads, the second package structure exposing the bottom side of each of the peripheral first leads, the second package structure exposing one lateral side of each of the peripheral first leads, the second package structure exposing the bottom side of each of the interior second leads.

11. The system of claim 10, further comprising a semiconductor die flip-chip attached to electrically connected to one of the interior second leads.

12. The system of claim 10, further comprising a wire bond connected between a semiconductor die and one of the interior second leads.

13. The system of claim 10, wherein:
the upper first portions of the lateral sides of the interior second leads have an outward taper in a direction toward a bottom side of the electronic device; and
the lower second portions of the lateral sides of the interior second leads have an inward taper in the direction toward the bottom side of the electronic device.

14. A method of fabricating an electronic device, the method comprising:
attaching a semiconductor die to a top side of a lead frame, the lead frame including a recess extending into the top side between a prospective peripheral first lead portion of the lead frame and a prospective interior second lead portion of the lead frame;
electrically connecting the semiconductor die to one of the prospective peripheral first lead portion and the prospective interior second lead portion of the top side of the lead frame;
performing a molding process that forms a package structure extending on the semiconductor die, on the top side of the lead frame, and into the recess; and
separating the prospective interior second lead portion from the rest of the lead frame.

15. The method of claim 14, wherein:
separating the prospective interior second lead portion from the rest of the lead frame forms an interior lead spaced apart from the rest of the lead frame and having lateral sides, a top side, and a bottom side;
the package structure is a first package structure that extends on the top side of the interior lead and on upper first portions of the lateral sides of the interior second lead; and
the method further comprises performing a second molding process that forms a second package structure that extends laterally around lower second portions of the lateral sides of the interior lead, the second package structure exposing the bottom side of the interior lead.

16. The method of claim 14, wherein separating the prospective interior second lead portion from the rest of the lead frame includes performing a laser process that removes material from a bottom side of a lead frame to expose a portion of the package structure in the recess.

17. The method of claim 14, further comprising separating the prospective peripheral first lead portion from the rest of the lead frame to form a peripheral first lead with a lateral side exposed outside the package structure.

18. The method of claim 14, wherein attaching the semiconductor die to the top side of the lead frame includes soldering a terminal of the semiconductor die to the top side of the lead frame.

19. The method of claim 14, wherein electrically connecting the semiconductor die to one of the prospective peripheral first lead portion and the prospective interior second lead portion includes connecting a wire bond between the semiconductor die and one of the prospective peripheral first lead portion and the prospective interior second lead portion before performing the molding process.

20. The method of claim 14, wherein electrically connecting the semiconductor die to one of the prospective peripheral first lead portion and the prospective interior second lead portion includes connecting a first wire bond between the semiconductor die and the prospective peripheral first lead portion and connecting a second bond wire between the semiconductor die and the prospective interior second lead portion before performing the molding process.
